(19) United States
(12) Patent Application Publication
(10) Pub. No.: US 2004/0137678 A1
(43) Pub. Date: Jul. 15, 2004

(54) Method for forming capacitor of semiconductor device

(76) Inventors: Ho Jin Cho, Sungnam-si (KR); Seung Woo Jin, Icheon-si (KR); Bong Soo Kim, Seoul (KR)

Correspondence Address: HELLER EHRMAN WHITE & MCAULIFFE LLP, 1666 K STREET,NW, SUITE 300, WASHINGTON, DC, 20006, US

(21) Appl. No.: 10/608,103

(22) Filed: Jun. 30, 2003

(30) Foreign Application Priority Data
Dec. 30, 2002 (KR) 2002-87079

(51) Int. Cl. H01L 21/8234; H01L 21/8244; H01L 21/8242; H01L 21/20

(52) U.S. Cl. 438/240; 438/396

(57) ABSTRACT

A method for forming capacitor of semiconductor device wherein a stacked structure of Al-rich HfO₂—Al₂O₃ film and Hf-rich HfO₂—Al₂O₃ film or a stacked structure of Al₂O₃ film and Hf-rich HfO₂—Al₂O₃ film is used as a dielectric film is disclosed. The method comprises (a) forming an oxide film on an interlayer insulating film having a storage electrode contact plug; (b) selectively etching the oxide film to form an opening exposing the top surface of the storage electrode contact plug; (c) forming a conductive layer on the bottom and the inner walls of the opening; (d) removing the oxide film to form a storage electrode; (e) forming a dielectric film having a stacked structure of Al-rich HfO₂—Al₂O₃ film and Hf-rich HfO₂—Al₂O₃ film on the surface of the storage electrode; (f) annealing the dielectric film; and (g) forming a plate electrode on the dielectric film.

### BACKGROUND OF THE INVENTION

1. Field of the Invention

The present invention relates to a method for forming capacitor of semiconductor device, and more particularly to a method for forming capacitor of semiconductor device wherein a stacked structure of Al-rich HfO₂—Al₂O₃ film and Hf-rich HfO₂—Al₂O₃ film or a stacked structure of Al₂O₃ film and Hf-rich HfO₂—Al₂O₃ film is used as a dielectric film to prevent reduction of a dielectric constant due to a silicon oxide film at an interface of a storage electrode and a dielectric film, thereby providing a capacitor having a high capacitance.

2. Description of the Background Art

As the size of a cell is decreased due to high integration of a semiconductor device, obtaining a sufficient capacitance of a capacitor which is proportional to an area of a storage electrode has become more difficult.

Specifically, in a DRAM wherein a unit cell is composed of one MOS transistor and one capacitor, increasing the capacitance of a capacitor which occupies a relatively large area decreasing the area occupied by the capacitor are one of the most important factor in achieving high integration of the DRAM device.

In order to increase the capacitance C of the capacitor which is represented by (∈o×∈r×A)/T (where ∈o is a vacuum dielectric constant, ∈r is a dielectric constant of a dielectric film, A is an area of a storage electrode, and T is a thickness of the dielectric film), a material having a high dielectric constant is used as the dielectric film, the thickness of the dielectric film is reduced, or the surface area of the storage electrode is increased.

As one of the methods for increasing the surface area of the storage electrode, forming a hemispherical polysilicon at sidewalls of a concave capacitor has been proposed. However, in the MIS structure of the highly integrated semiconductor device having a design rule of 0.12 μm or less, a tantalum oxide film, which is used as a dielectric film, having an oxide equivalent thickness (Tox) of 28 Å or less is difficult to obtain.

FIG. 1 is a cross-sectional diagram illustrating a portion of a conventional capacitor of a semiconductor device.

Referring to FIG. 1, an interlayer insulating film (not shown) is formed on a semiconductor substrate (not shown) including lower structures such as device isolation film (not shown), an impurity junction area (not shown), a word line (not shown), a bit line (not shown) and a storage electrode contact plug (not shown).

An oxide film for storage electrode (not shown) is formed on the entire surface of the resulting structure. The oxide film for the storage electrode (not shown) contains an impurity.

The oxide film for storage electrode (not shown) selectively etched according to a photoetching process using a storage electrode mask (not shown) to form an opening (not shown) exposing the storage electrode contact plug (not shown).

Thereafter, a conductive layer for storage electrode (not shown) is deposited on the entire surface of the resulting structure including a surface of the opening (not shown) to contact the storage electrode contact plug (not shown). The conductive layer for storage electrode is a doped polysilicon film 11.

A photoresist film (not shown) filling the opening (not shown) is formed on the entire surface of the resulting structure, and then planarized to expose the oxide film for storage electrode (not shown).

The photoresist film (not shown) is removed to form a storage electrode on the surface of the opening (not shown). A hemispherical polysilicon film can be additionally formed on the surface of the storage electrode.

The oxide film for storage electrode (not shown) is removed, and a tantalum oxide film 15, which is a dielectric film, is formed on the doped polysilicon film 11, which is the storage electrode. A silicon oxide film 13 is formed at an interface of the tantalum oxide film 15 and the doped polysilicon film 11.

An N₂O or O₂ annealing process is performed to prevent crystallization and oxygen deficiency of the tantalum oxide film 15. A silicon oxide nitride film 17 is formed at the interface of the doped polysilicon film 11 and the tantalum oxide film 15, and thus the Tox of the tantalum oxide film 15 including the silicon oxide nitride film 17 is greater than 28 Å. As a result, a capacitance of the capacitor sufficient for the design rule of 0.12 μm cannot be obtained.

Accordingly, a height of the storage electrode must be increased to obtain a sufficient capacitance for highly integrated semiconductor device. However, when the height of the storage electrode is increased, defects are generated in the device and a yield of the device is reduced due to collapse of the storage electrode.

FIGS. 2a and 2b are a photograph illustrating a cross-section of another concentrated capacitor of the semiconductor device, and graphs illustrating intensity of a high dielectric constant oxide film according to sputtering time.

As illustrated in FIG. 2a, an HfO₂ film 25 which is an oxide film having a high dielectric constant is deposited on a doped polysilicon film 21 which is a conductive layer for storage electrode and then annealed to form a dielectric film, and a plate electrode 27 is formed on the resulting structure.

A silicon oxide film or HfSiOₓ film 23 having a low dielectric constant is formed at an interface of the. HfO₂ film 25 and the doped polysilicon film 21 during the annealing process, which reduces a dielectric constant of the dielectric film.

FIGS. 2a and 2b are Auger electron spectroscopy (AES) depth profile data. The sputtering time represents a sputtering etching time of a thin film using Ar ions. Time lapse means that the etching progresses from the surface of the thin film to the inside of the bulk. The intensity represents an intensity of Auger electrons (AE). A high intensity implies a large content of AE.

As described above, in accordance with the conventional method for forming the capacitor of the semiconductor device, when the tantalum oxide film is used as the dielectric film, capacitance sufficient for high integration cannot be obtained due to a large Tox, and when the HfO₂ film is used as the dielectric film, a thin film having a low dielectric constant is generated during the annealing process. As a result, the dielectric constant of the semiconductor device is reduced, and the capacitance sufficient for high integration is not obtained.

### SUMMARY OF THE INVENTION

It is an object of the present invention to provide a method for forming a capacitor of a semiconductor device wherein a stacked structure of Al-rich HfO₂—Al₂O₃ film and Hf-rich HfO₂—Al₂O₃ film or a stacked structure of Al₂O₃ film and Hf-rich HfO₂—Al₂O₃ film is used as a dielectric film to prevent reduction of a dielectric constant due to a silicon oxide film at an interface of a storage electrode and a dielectric film, thereby providing a capacitor having a high capacitance.

In accordance with one aspect of the present invention, a method for forming a capacitor of a semiconductor device, comprising the steps of: (a) forming an oxide film on an interlayer insulating film having a storage electrode contact plug; (b) selectively etching the oxide film to form an opening exposing the top surface of the storage electrode contact plug; (c) forming a conductive layer on the bottom and the inner walls of the opening; (d) removing the oxide film to form a storage electrode; (e) forming a dielectric film having a stacked structure of Al-rich HfO₂—Al₂O₃ film and Hf-rich HfO₂—Al₂O₃ film on the surface of the storage electrode; (f) annealing the dielectric film; and (g) forming a plate electrode on the dielectric film is provided.

In accordance with another aspect of the present invention, a method for forming a capacitor of a semiconductor device, comprising the steps of: (a) forming an oxide film on an interlayer insulating film having a storage electrode contact plug; (b) selectively etching the oxide film to form an opening exposing the top surface of the storage electrode contact plug; (c) forming a conductive layer on the bottom and the inner walls of the opening; (d) removing the oxide film to form a storage electrode; (e) forming a dielectric film using Al-rich HfO₂—Al₂O₃ film on the surface of the storage electrode; (f) annealing the dielectric film; and (g) forming a plate electrode on the dielectric film is provided.

In accordance with yet another aspect of the present invention, a method for forming a capacitor of a semiconductor device, comprising the steps of: (a) forming an oxide film on an interlayer insulating film having a storage electrode contact plug; (b) selectively etching the oxide film to form an opening exposing the top surface of the storage electrode contact plug; (c) forming a conductive layer on the bottom and the inner walls of the opening; (d) removing the oxide film to form a storage electrode; (e) forming a dielectric film having a stacked structure of Al₂O₃ film and Hf-rich HfO₂—Al₂O₃ film on the surface of the storage electrode; (f) annealing the dielectric film; and (g) forming a plate electrode on the dielectric film.

### BRIEF DESCRIPTION OF THE DRAWINGS

The present invention will become better understood with reference to the accompanying drawings which are given only by way of illustration and thus are not limitative of the present invention, wherein:

FIG. 1 is a cross-sectional diagram illustrating a portion of a conventional capacitor of a semiconductor device;

FIG. 2 is a photograph illustrating a cross-section of another conventional capacitor.

FIGS. 3a and 3b are graphs showing characteristic variations of a dielectric film of the capacitor shown in FIG. 2;

FIGS. 4a to 4f are cross-sectional diagrams illustrating sequential steps of a method for forming a capacitor of a semiconductor device in accordance with a preferred embodiment of the present invention; and

FIG. 4 is a graph illustrating a thickness of a dielectric film according to a deposition thickness of a thin film having a high dielectric constant.

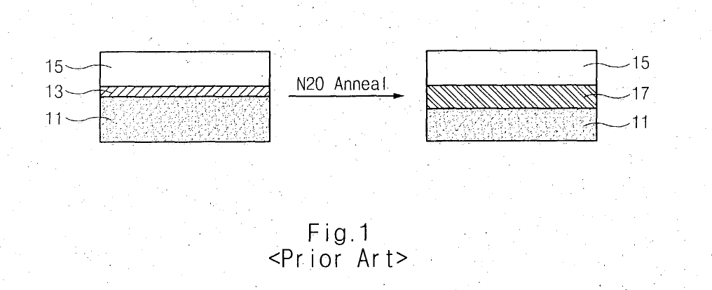

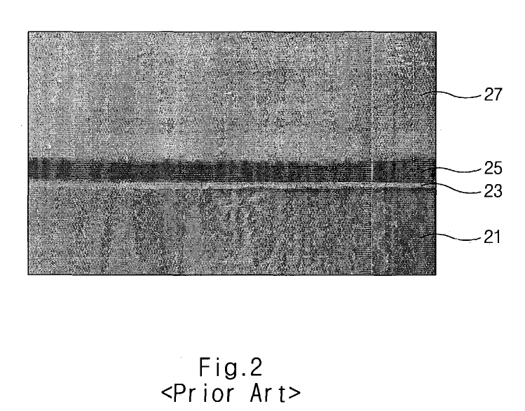

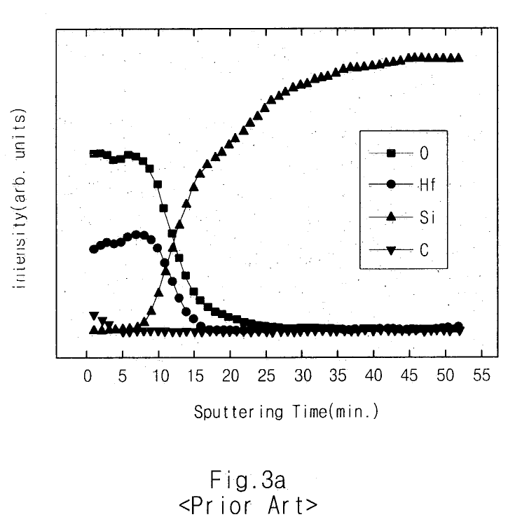

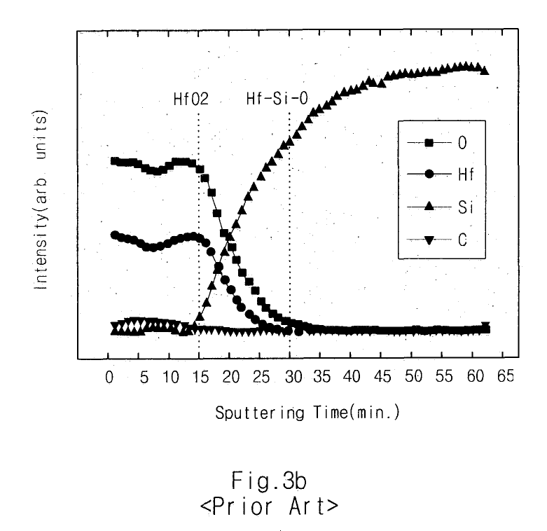

### DETAILED DESCRIPTION OF THE PREFERRED EMBODIMENTS

A method for forming a capacitor of a semiconductor device in accordance with a preferred embodiment of the present invention will now be described in detail with reference to the accompanying drawings.

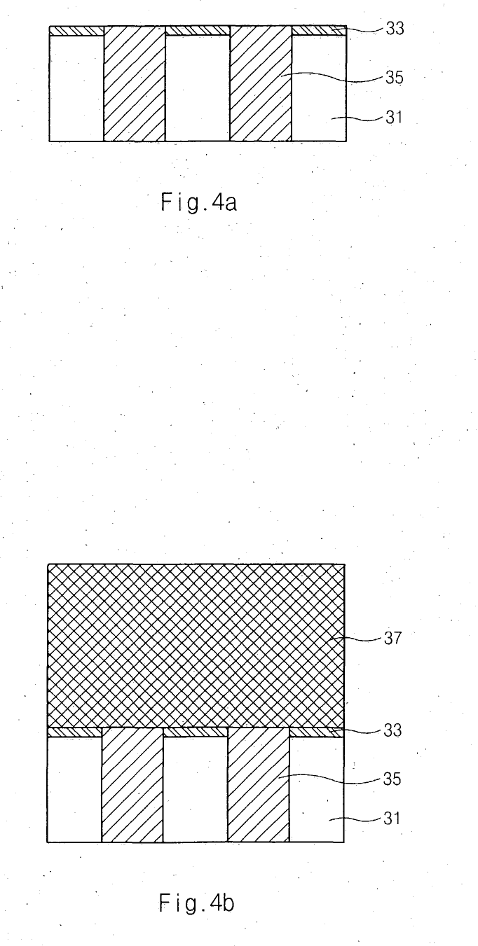

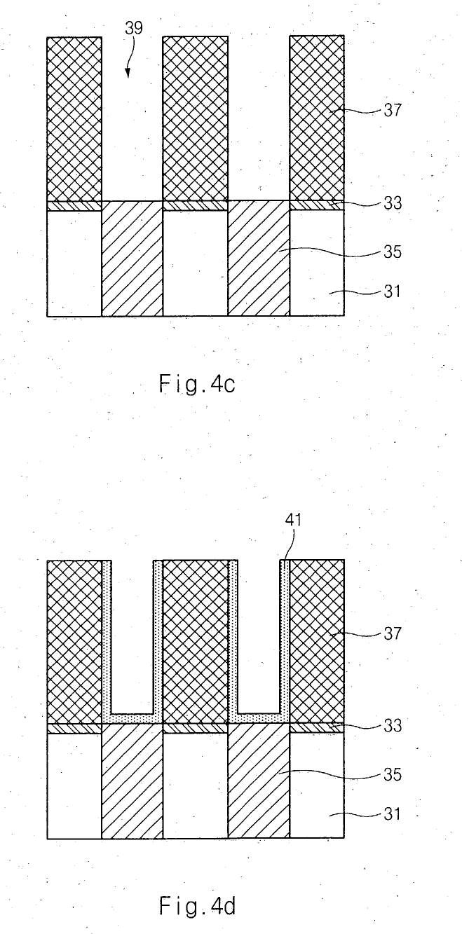

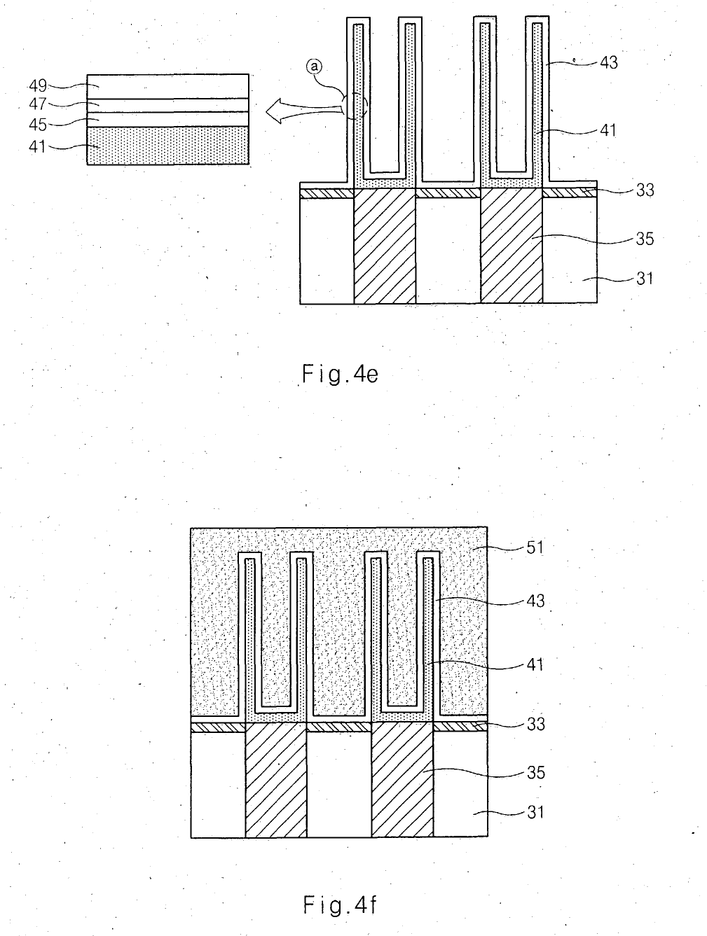

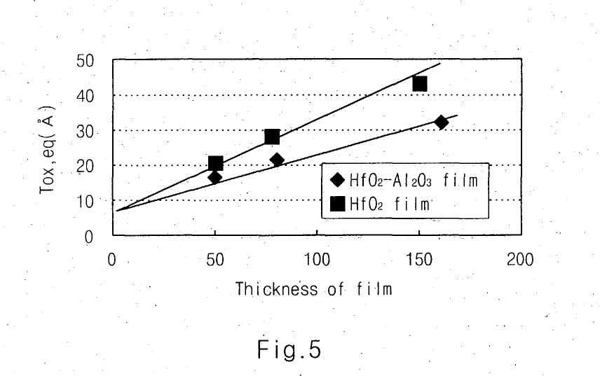

FIGS. 4a to 4f are cross-sectional diagrams illustrating sequential steps of a method for forming a capacitor of a semiconductor device in accordance with a preferred embodiment of the present invention.

Referring to FIG. 4a, a device isolation film (not shown), an impurity junction area (not shown), a word line (not shown) and a bit line (not shown) are formed on a semiconductor substrate. A planarized interlayer insulating film 31 is then formed on the resulting structure.

Thereafter, an etch barrier layer 33 which is preferably a nitride film is formed on the interlayer insulating film 31, and the resulting structure is etched via a photoetching process using a storage electrode contact mask (not shown) to form a storage electrode contact hole. Next, the storage electrode contact hole is filled with a conductive material to form a storage electrode contact plug 35.

Referring to FIG. 4b, an oxide film 37 for storage electrode is formed on the entire surface of the resulting structure. The oxide film 37 for storage electrode is preferably a conventional oxide film used in manufacturing process of semiconductor devices.

Now referring to FIG. 4c, the oxide film 37 for storage electrode is selectively etched according to a photoetching process using a storage electrode mask (not shown) to form an opening 39 exposing the storage electrode contact plug 35.

Referring to FIG. 4d, a conductive layer for storage electrode (not shown), which is preferably a doped polysilicon film, is formed on the entire surface of the resulting structure including a surface of the opening 39. Thereafter, a photoresist film (not shown) is formed on the entire surface of the resulting structure, and then planarized to expose the oxide film for storage electrode 37. The photoresist film is then removed, thereby forming a storage electrode 41. The storage electrode 41 can further include a hemispherical polysilicon film (not shown) on its surface. Preferably, the storage electrode 41 including the hemispherical polysilicon film are formed by stacking a doped amorphous silicon film and an undoped amorphous silicon film, performing an annealing process to grow the undoped amorphous silicon film into the hemispherical polysilicon film, and performing a succeeding annealing process.

Now referring to FIG. 4e, the oxide film for storage electrode 37 is removed by utilizing etching selectivity thereof over adjacent layers.

A chemical oxide film (not shown) having a thickness ranging from 3 to 5 Å is formed by cleaning the surface of the storage electrode 41 in a cleaning solution in which the composition ratio of NH₄OH:H₂O₂:H₂ is 1:(4˜5):(20˜50). Alternatively, an oxide film (not shown) having a thickness ranging from 8 to 15 Å is formed by cleaning the surface of the storage electrode 41 in an HF or BOE solution and performing an RTO process.

A dielectric film 43 is formed on the entire surface of the resulting structure. The dielectric film 43 is preferably formed by sequentially depositing a film 47 containing mixture of HfO₂ and Al₂O₃ rich in Al(“Al-rich HfO₂—Al₂O₃ film”) and a film 49 containing mixture of HfO₂ and Al₂O₃ rich in Hf(“Hf-rich HfO₂—Al₂O₃ film”), and then annealing the resulting structure. Alternatively, pure Al₂O₃ film may be used instead of Al-rich HfO₂—Al₂O₃ film. Preferably, as an another embodiment, the dielectric film 43 may be formed without the Hf-rich HfO₂—Al₂O₃ film, i.e. only using an Al-rich HfO₂—Al₂O₃ film. A silicon oxide film 45 is formed at an interface of the storage electrode 41 consisting of doped silicon and the Al-rich HfO₂—Al₂O₃ film 47. However, the silicon oxide film 45 is removed because Al₂O₃ which has higher oxidizing power than SiO₂ converts SiO₂ into Al₂O₃ during the annealing process. As a result, the reduction of dielectric constant due to the silicon oxide film 45 is prevented.

Preferably, the Al-rich HfO₂—Al₂O₃ film 47 and the Hf-rich HfO₂—Al₂O₃ film 49 have a thickness ranging from 5 to 30 Å and 10 to 100 Å, respectively, and formed according to an ALD process. Specifically, the ALD process is performed at a temperature ranging from 150 to 600° C. using Al(CH₄)₃ as an Al source, HfCl₄ as a Hf source and H₂O as an O source. One cycle of Al₂O₃ comprises Al pulse, N₂ purge, H₂O pulse and N₂ purge processes, and one cycle of HfO₂ comprises Hf pulse, N₂ purge, H₂O pulse and N₂ purge processes.

In addition, the Hf source may be selected from the group consisting of HfCl₄, Hf[N(C₂H₅)₂]₄, HF[N(CH₃)₂]₄, Hf[N(CH₃)(C₂H₅)]₄, Hf[OC(CH₃)₃]₄, Hf(NO₃)₄, and combinations thereof, the O source may be selected from the group consisting of H₂O, O₂, N₂O, O₃, and combinations thereof, and one cycle of HfO₂ may comprise Hf pulse, N₂ purge, O pulse and N₂ purge.

Preferably, a ratio of HfO₂ to Al₂O₃ cycles in the formation process of the Al-rich HfO₂—Al₂O₃ film 47 is (1 cycle:1 cycle)˜(9 cycle:1 cycle), and a ratio of HfO₂ to Al₂O₃ in the formation process of the Hf-rich HfO₂—Al₂O₃ film 49 is (9 cycle:1 cycle)˜(2 cycle:1 cycle).

The annealing process is performed according to a rapid thermal annealing process at a temperature ranging from 500 to 900° C. under oxygen or nitrogen gas atmosphere for 1 to 10 minutes. Alternatively, the annealing process is performed in a furnace at a temperature ranging from 500 to 900° C. under oxygen, nitrogen or N₂O gas atmosphere for 10 to 60 minutes.

Referring to FIG. 4f, a plate electrode 51 is formed on the dielectric film 43. The plate electrode 51 is preferably formed according to a CVD process using one material selected from the group consisting of TaN, TiN, WN, W, Pt, Ru, Ir, doped polysilicon, and combinations thereof.

FIG. 4 is a graph illustrating a thickness of the dielectric films according to a deposition thickness of a thin film of the present invention and the conventional arts. As shown in FIG. 4, the HfO₂—Al₂O₃ film of the invention has a smaller thickness.

In accordance with the present invention, generation of the silicon oxide film at the interface of the storage electrode and the dielectric film is controlled, by forming the dielectric film comprising the stacked structure of the Al-rich HfO₂—Al₂O₃ film and the Hf-rich HfO₂—Al₂O₃ film, or the stacked structure of Al₂O₃ film and Hf-rich HfO₂—Al₂O₃ film, thereby preventing reduction of the dielectric constant and providing the large capacitance.

As the present invention may be embodied in several forms without departing from the spirit or essential characteristics thereof, it should also be understood that the above-described embodiment is not limited by any of the details of the foregoing description, unless otherwise specified, but rather should be construed broadly within its spirit and scope as defined in the appended claims, and therefore all changes and modifications that fall within the metes and bounds of the claims, or equivalences of such metes and bounds are therefore intended to be embraced by the appended claims.

What is claimed is:

1. A method for forming a capacitor of a semiconductor device, comprising the steps of:
(a) forming an oxide film on an interlayer insulating film having a storage electrode contact plug;
(b) selectively etching the oxide film to form an opening exposing the top surface of the storage electrode contact plug;
(c) forming a conductive layer on the bottom and the inner walls of the opening;
(d) removing the oxide film to form a storage electrode;
(e) forming a dielectric film having a stacked structure of Al-rich HfO₂—Al₂O₃ film and Hf-rich HfO₂—Al₂O₃ film on the surface of the storage electrode;
(f) annealing the dielectric film; and
(g) forming a plate electrode on the dielectric film.

2. The method of claim 1, further comprising the step of cleaning the surface of the storage electrode with a cleaning solution of NH₄OH:H₂O₂:H₂=1:(4˜5):(20˜50) after the step (d) to form an oxide film having a thickness ranging from 3 to 5 Å on a surface of the storage electrode.

3. The method of claim 1, further comprising the step of cleaning the surface of the storage electrode with an HF or BOE solution and performing an RTO process after the step (d) to form an oxide film having a thickness ranging from 8 to 15 Å.

4. The method of claim 1, wherein the step (e) is performed in an ALD process and the thickness of the Al-rich HfO₂—Al₂O₃ film and the Hf-rich HfO—Al₂O₃ film is 5 to 30 Å and 10 to 100 Å, respectively.

5. The method of claim 1, wherein the step (e) is performed in an ALD process using Al(CH₄)₃ as an Al source, HfCl₄ as an Hf source and H₂O, O₃, O₂ and N₂O as an O source, one cycle for Al₂O₃ ALD process comprising Al pulse, N₂ purge, O pulse and N₂ purge, and one cycle of HfO₂ of the ALD process comprising Hf pulse, N₂ purge, O pulse and N₂ purge processes.

6. The method of claim 1, wherein the step (e) is an ALD or CVD process performed at a temperature of 150 to 600° C.

7. The method of claim 1, wherein the step (e) is an ALD process using a Hf source selected from the group consisting of HfCl₄, Hf[N(C₂H₅)₂]₄, HF[N(CH₃)₂]₄, Hf[N(CH₃)(C₂H₅)]₄, Hf[OC(CH₃)₃]₄, Hf(NO₃)₄, and combinations thereof, and an O source selected from the group consisting of H₂O, O₂, N₂O, O₃, and combinations thereof, one cycle of HfO₂ of the ALD process comprising Hf pulse, N₂ purge, O pulse and N₂ purge in.

8. The method of claim 1, wherein a ratio of HfO₂:Al₂O₃ in the Al-rich HfO₂—Al₂O₃ film ranges from (1 cycle:1 cycle)˜(9 cycle:1 cycle).

9. The method of claim 1, wherein a ratio of HfO₂:Al₂O₃ in the Hf-rich HfO₂—Al₂O₃ film ranges from (9 cycle:1 cycle)˜(2 cycle:1 cycle).

10. The method of claim 1, wherein the step (f) is performed at a temperature ranges from 500 to 900° C. under oxygen or nitrogen gas atmosphere for 1 to 10 minutes.

11. The method of claim 1, wherein the step (f) is performed in a furnace at a temperature ranges from 500 to 900° C. under oxygen, nitrogen or N₂O gas atmosphere for 10 to 60 minutes.

12. The method of claim 1, wherein the step (g) is a CVD process for forming the plate electrode using a material selected from the group consisting of TaN, TiN, WN, W, Pt, Ru, Ir, doped polysilicon, and combinations thereof.

13. A method for forming a capacitor of a semiconductor device, comprising the steps of:
(a) forming an oxide film on an interlayer insulating film having a storage electrode contact plug;
(b) selectively etching the oxide film to form an opening exposing the top surface of the storage electrode contact plug;
(c) forming a conductive layer on the bottom and the inner walls of the opening;
(d) removing the oxide film to form a storage electrode;
(e) forming a dielectric film using Al-rich HfO₂—Al₂O₃ film on the surface of the storage electrode;
(f) annealing the dielectric film; and
(g) forming a plate electrode on the dielectric film.

14. A method for forming a capacitor of a semiconductor device, comprising the steps of:
(a) forming an oxide film on an interlayer insulating film having a storage electrode contact plug;
(b) selectively etching the oxide film to form an opening exposing the top surface of the storage electrode contact plug;
(c) forming a conductive layer on the bottom and the inner walls of the opening;
(d) removing the oxide film to form a storage electrode;
(e) forming a dielectric film having a stacked structure of Al₂O₃ film and Hf-rich HfO₂—Al₂O₃ film on the surface of the storage electrode;
(f) annealing the dielectric film; and
(g) forming a plate electrode on the dielectric film.
